(19) United States
(12) Patent Application Publication
(10) Pub. No.: US 2013/0242640 A1
(43) Pub. Date: Sep. 19, 2013

(54) Methods and Systems for Resistive Change Memory Cell Restoration

(71) Applicants: Brent Steven Haukness, Monte Sereno, CA (US); Mark D. Kellam, Siler City, NC (US)

(72) Inventors: Brent Steven Haukness, Monte Sereno, CA (US); Mark D. Kellam, Siler City, NC (US)

(21) Appl. No.: 13/789,557

(22) Filed: Mar. 7, 2013

Related U.S. Application Data
(60) Provisional application No. 61/608,065, filed on Mar. 7, 2012.

(51) Int. Cl. G11C 13/00

(52) U.S. Cl. CPC G11C 13/0069
USPC 365/148

(57) ABSTRACT

A resistive change memory device includes a first conductive line, a second conductive line, and a resistive change memory cell that includes a resistive memory element coupled between the first conductive line and the second conductive line. The resistive change memory device also includes control circuitry to apply, via the first conductive line and the second conductive line, a first biasing condition to the resistive change memory cell for a reset operation and a second biasing condition to the resistive change memory cell for a restore operation. The restore operation is performed to counteract a decrease in resistance of the resistive memory element for a reset state of the resistive change memory cell. At least one of a voltage, current, and duration of the second biasing condition is greater than a corresponding voltage, current, or duration of the first biasing condition.

### RELATED APPLICATIONS

This application claims priority to U.S. Provisional Application No. 61/608,065, filed Mar. 7, 2012, which is hereby incorporated by reference in its entirety.

### BACKGROUND

Ensuring the long-term reliability of resistive change memory devices presents significant engineering challenges. For example, the resistance of a high-resistance state for a resistive change memory cell may decrease over time as the resistive change memory cell is repeatedly programmed. This decrease causes the resistive change memory cell, and thus of the resistive change memory device that includes the resistive change memory cell, to have what is referred to herein as write endurance. The term “write endurance” means the number of set/reset cycles a resistive change memory cell undergoes before the reset resistance and the set resistance of the resistive change memory cell cannot be distinguished rapidly and reliably. Accordingly, there is a need for techniques to counteract this decrease in resistance.

### BRIEF DESCRIPTION OF THE DRAWINGS

FIG. 1 is a prophetic example of a graph of read current versus the number of set/reset cycles that have been performed on a resistive change memory cell in a resistive change memory device in accordance with some embodiments.

FIGS. 2A-2D are schematic diagrams of resistive change memory cells in accordance with some embodiments.

FIGS. 3A-3E are schematic diagrams of arrays of resistive change memory cells along with circuitry to bias the resistive change memory cells for set, reset, and restore operations in accordance with some embodiments.

FIG. 4A is a block diagram illustrating a read/write circuit in accordance with some embodiments.

FIG. 4B is a block diagram illustrating an alternative implementation of read/write circuit in accordance with some embodiments.

FIG. 5 is a block diagram of a resistive change memory device in accordance with some embodiments.

FIGS. 6A-6C are flow diagrams illustrating methods of operating a resistive change memory device in accordance with some embodiments.

Like reference numerals refer to corresponding parts throughout the drawings.

### DESCRIPTION OF EMBODIMENTS

In some embodiments, a resistive change memory device includes a first conductive line, a second conductive line, and a resistive change memory cell that includes a resistive memory element coupled between the first conductive line and the second conductive line. The resistive change memory device also includes control circuitry to apply, via the first conductive line and the second conductive line, a first biasing condition to the resistive change memory cell for a reset operation and a second biasing condition to the resistive change memory cell for a restore operation. The restore operation is performed to counteract a decrease in resistance of the resistive memory element for a reset state of the resistive change memory cell. At least one of a voltage, current, and duration of the second biasing condition is greater than a corresponding voltage, current, or duration of the first biasing condition.

In some embodiments, a method includes providing a resistive change memory device including a resistive change memory cell that includes a resistive memory element. A first biasing condition is applied to the resistive change memory cell for a reset operation. A second biasing condition is applied to the resistive change memory cell for a restore operation to counteract the decrease in resistance of the resistive change memory cell in the reset state. At least one of a voltage, current, and duration of the second biasing condition is greater than a corresponding voltage, current, or duration of the first biasing condition.

Reference will now be made in detail to various embodiments, examples of which are illustrated in the accompanying drawings. In the following detailed description, numerous specific details are set forth in order to provide a thorough understanding of the disclosed embodiments. However, embodiments may be practiced without these specific details. In other instances, well-known methods, procedures, components, and circuits have not been described in detail so as not to unnecessarily obscure aspects of the embodiments.

A resistive change memory device includes an array of resistive change memory cells, each of which includes a resistive memory element. The resistive memory element includes a resistance-switching material situated between two electrodes. The resistance-switching material has at least two states, a high-resistance state and a low-resistance state, and can be cycled between these two states by application of appropriate voltages to the electrodes, thus allowing the resistive memory element to be programmed. For example, a resistive change memory cell for which the resistance-switching material has been programmed to the high-resistance state (referred to herein as a “reset” state) is considered to store a “1” and a resistive change memory cell for which the resistance-switching material has been programmed to the low-resistance state (referred to herein as a “set” state) is considered to store a “0,” or vice-versa.

Four general classes of resistance-switching materials are solid electrolyte materials, insulating materials, phase-change materials, and organic materials. The term “resistive change memory device” as used herein includes, without limitation, memories that use any of these classes of resistance-switching materials (e.g., resistance-switching random access memories (RRAMs), conductive-bridging random access memories (CB-RAMs), and phase-change memories (PRAMs)). Examples of resistance-switching electrolyte materials include GeₓSe₁₋ₓ, GeₓS₁₋ₓ, Cu₂S, CuO, Ag₂S, WO₃, CeO, HfO₂, and SiO₂. Examples of resistance-switching insulating materials include TiO₂, NiO, SrZrO₃, SrTiO₃, ZrO₂, Mo, and MgO.

A resistive change memory cell using a solid electrolyte material as the resistance-switching material is typically fabricated using a metal that exhibits ionic conductivity in the solid electrolyte (i.e., a metal ion source for the solid electrolyte) as the first electrode and an inert metal as the second electrode. Application of a biasing condition (e.g., a first bias voltage applied for a specified duration) that corresponds to a set operation causes the first electrode to inject ions into the solid electrolyte; the ions precipitate into filaments that produce low-resistance paths between the electrodes, resulting in formation of a low-resistance state (or set state) in the solid electrolyte. Application of a biasing condition (e.g., a second bias voltage distinct from the first bias voltage, applied for a specified duration) that corresponds to a reset operation causes the dissolution of the filaments, resulting in formation of a high-resistance state (or reset state) in the solid electrolyte. (While other types of resistance-switching materials may operate in accordance with other physical mechanisms, the materials also may be programmed to low-resistance (set) and high-resistance (reset) states). The reset operation, however, does not entirely reverse the set operation: some ions injected into the solid electrolyte during the set operation remain in the solid electrolyte after the reset operation. Over time, these ions accumulate in the solid electrolyte as the resistive change memory cell is repeatedly cycled between set and reset states, resulting in a decrease in the resistive change memory cell's reset resistance (i.e., the resistance in the reset state). Similarly, ions may also accumulate in the form of reduced metal at the inert electrode leading to a reduction in the effective thickness of the electrolyte and reducing the resistive change memory cell's resistance in the high resistance state. Eventually the reset resistance and the set resistance of the resistive change memory cell change to a point at which the reset resistance and the set resistance cannot be distinguished rapidly and reliably. When this occurs, the resistive change memory cell can be regarded as no longer being functional.

A newly-fabricated resistive change memory cell has a specified write endurance. The write endurance is the maximum number of set/reset cycles the memory cell will undergo before the above-described degradation mechanisms make the reset resistance and the set resistance of the resistive change memory cell difficult to distinguish rapidly and reliably. Each set/reset cycle that the memory cell undergoes degrades the difference between the reset resistance and the set resistance. Thus, at any point in its lifetime, a resistive change memory cell can be regarded as having what will be referred to as future endurance. The future endurance of a resistive memory cell represents the number of set/reset cycles the memory cell will be able to undergo before the memory cell ceases to be functional.

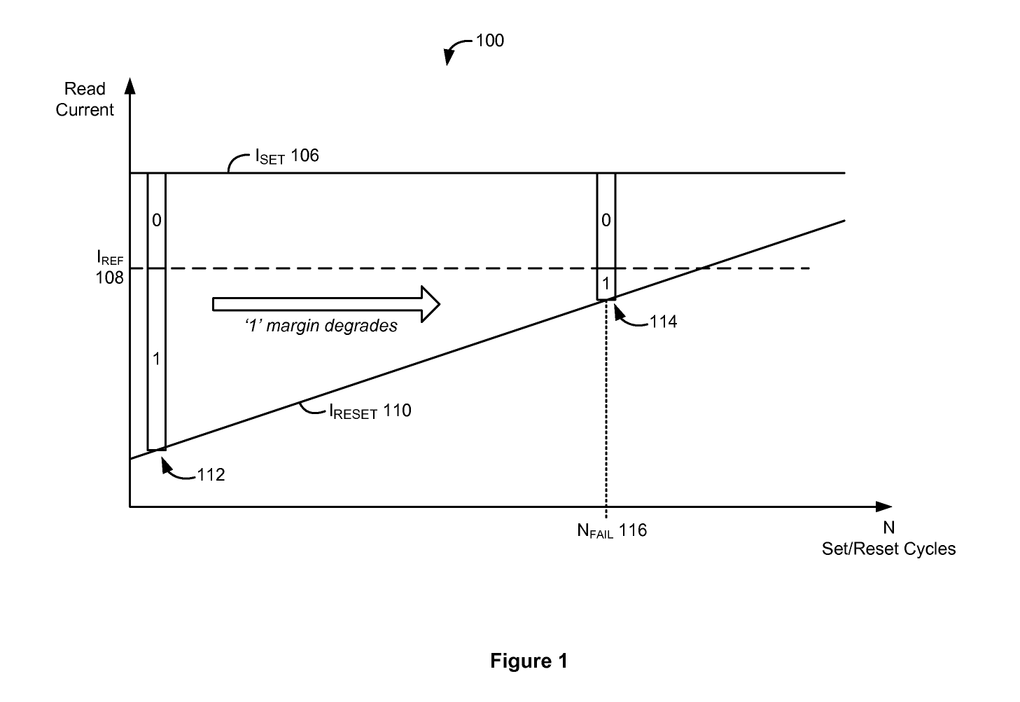

FIG. 1 shows a prophetic example of a graph 100 of read current versus the number N of set/reset cycles that have been performed on a resistive change memory cell in a resistive change memory device in accordance with some embodiments. I_{SET} 106 shows the read current for the resistive change memory cell in a set state and I_{RESET} 110 shows the read current for the resistive change memory cell in a reset state. I_{SET} 106 is greater than I_{RESET} 110 because the resistive change memory cell's resistance in the set state is less than the resistive change memory cell's resistance in the reset state. In some embodiments, a read operation for the resistive change memory cell is performed by comparing the resistive change memory cell's read current to a reference current I_{REF} 108. In the example of FIG. 1, the resistive change memory cell is assumed to store a “1” in the reset state and a “0” in the set state. Thus, if the resistive change memory cell's read current is found to be less than I_{REF} 108, a determination is made that the resistive change memory cell stores a “1,” and if the resistive change memory cell's read current is found to be greater than I_{REF} 108, a determination is made that the resistive change memory cell stores a “0.” I_{RESET} 110 increases as the number of set/reset cycles increases, indicating that the resistive change memory cell's reset resistance is decreasing with increasing numbers of set/recycles. At a first point 112, I_{RESET} has sufficient margin with respect to I_{REF} 108 to allow a “1” stored in the resistive change memory cell to be read rapidly and reliably. At a second point 114, however, the reset resistance has decreased by an amount such that I_{RESET} no longer has sufficient margin with respect to I_{REF} 108 to allow a “1” stored in the resistive change memory cell to be read rapidly and reliably. The number of cycles (N_{FAIL}) 116 corresponding to the second point 114 represents the write endurance of the resistive change memory cell: the resistive change memory cell is deemed to have failed when the number of set/reset cycles 104 exceeds N_{FAIL} 116. Note that although I_{RESET} 110 is illustrated as being a linear function of the number N of set/reset cycles, in general I_{RESET} 110 (and hence, the resistive change memory cell's resistance) is a monotonic function (and in some implementations a non-linear monotonic function) of the number N of set/reset cycles.

In some embodiments, to at least partially reverse the decrease in reset resistance resulting from subjecting the resistive change memory cell to repeated set/reset cycles, a restore operation is performed under a more extreme biasing condition, referred to as a second biasing condition, than the biasing condition for the reset operation, which is referred to as a first biasing condition. Each biasing condition involves applying a specified voltage to a resistive change memory cell for a specified duration, or alternatively applying a specified current to a resistive change memory cell for a specified duration. For example, the specified voltage (or current) of the second biasing condition has a greater magnitude than, but the same polarity as, the specified voltage (or current) of the first biasing condition, and/or the specified duration of the second biasing condition is greater than the specified duration of the first biasing condition. Because the second biasing condition is more extreme than the first biasing condition, the restore operation more effectively reverses the set operation than does the reset operation. For example, the second biasing condition results in greater migration of ions out of the solid electrolyte onto the electrode than does the first biasing condition. Performing a restore operation increases the future endurance of the resistive change memory cell and therefore increases the number of set/reset cycles the resistive change memory cell can undergo to a value greater than the cell's specified write endurance.

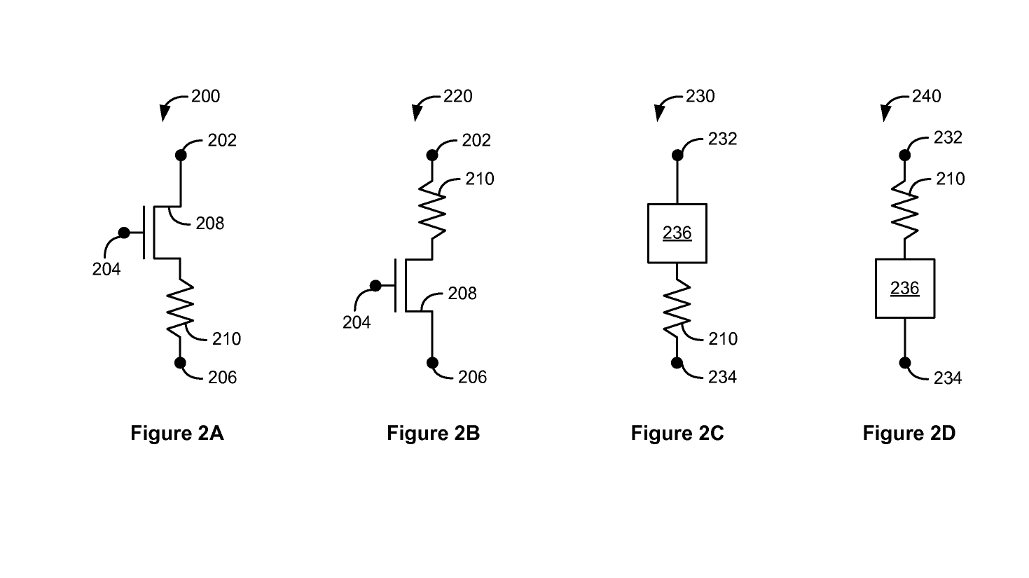

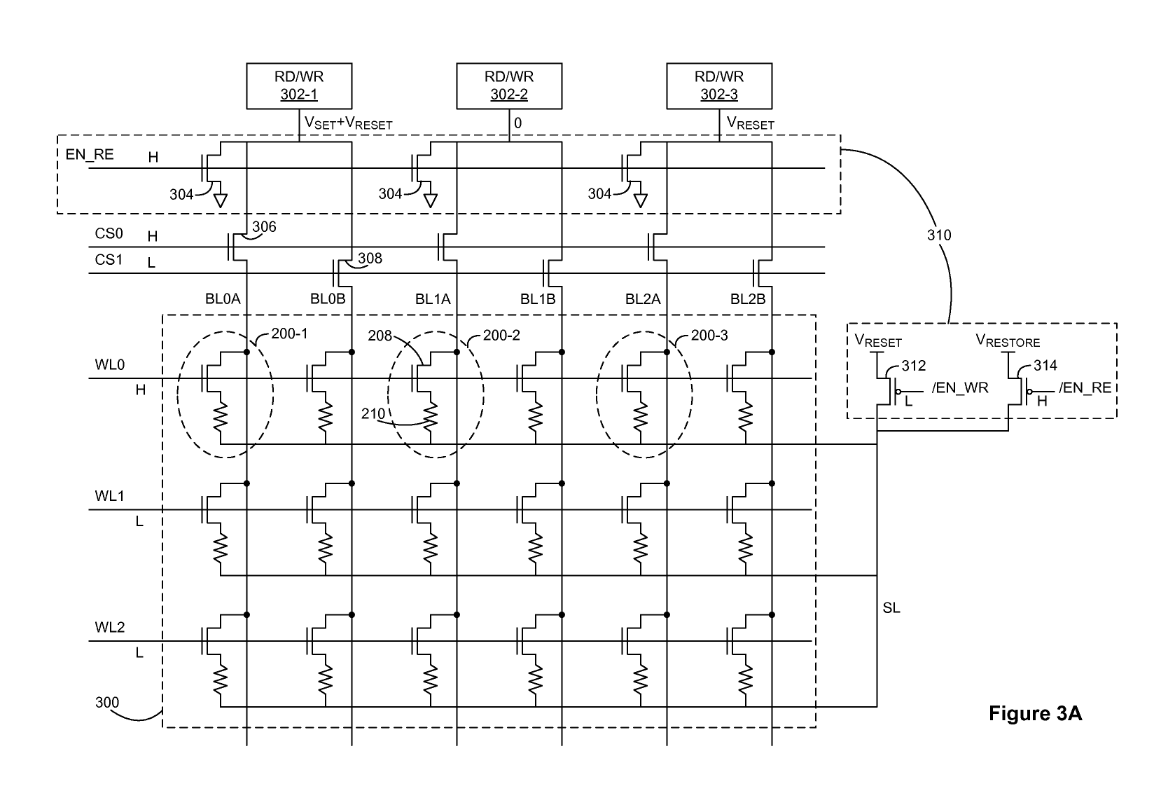

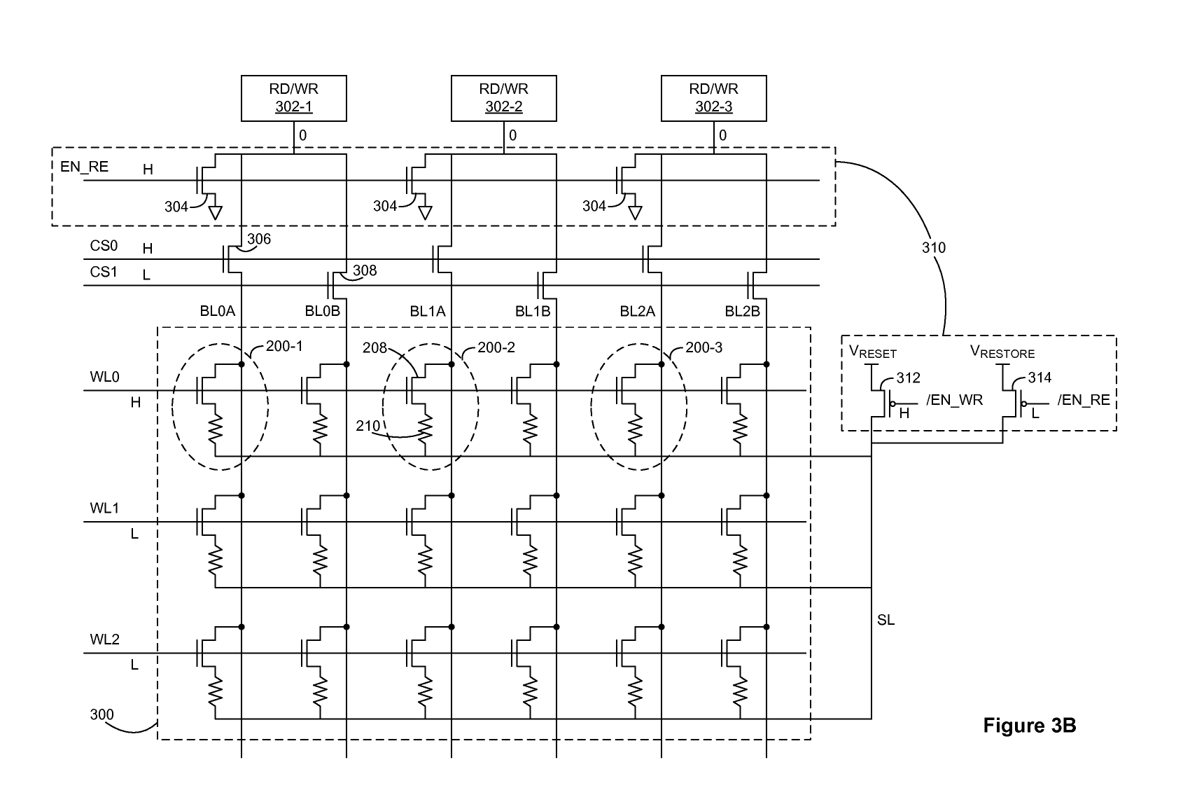

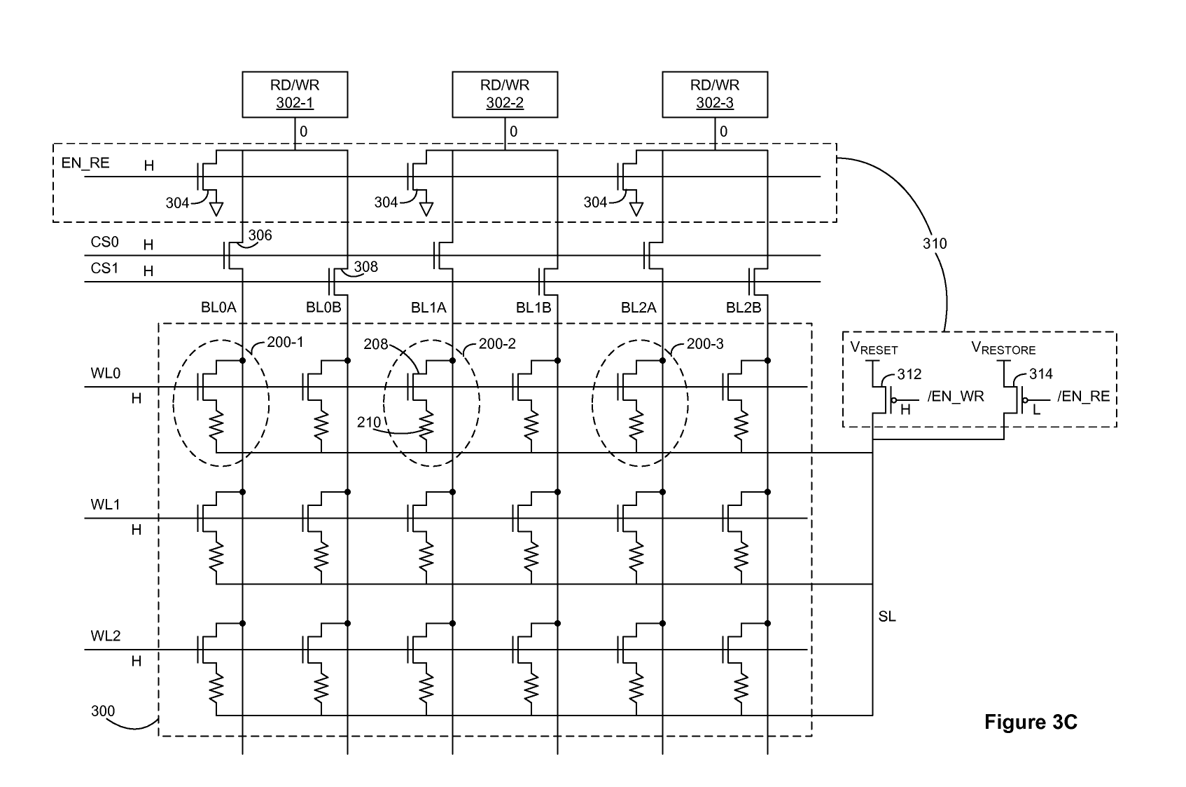

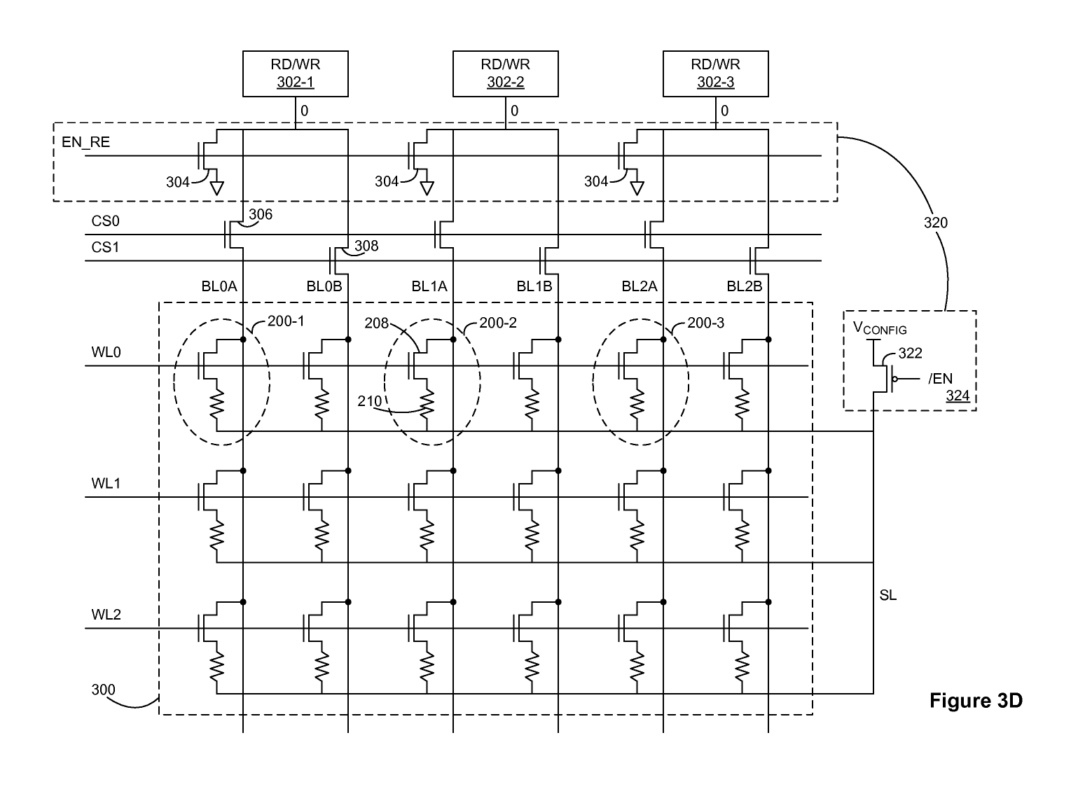

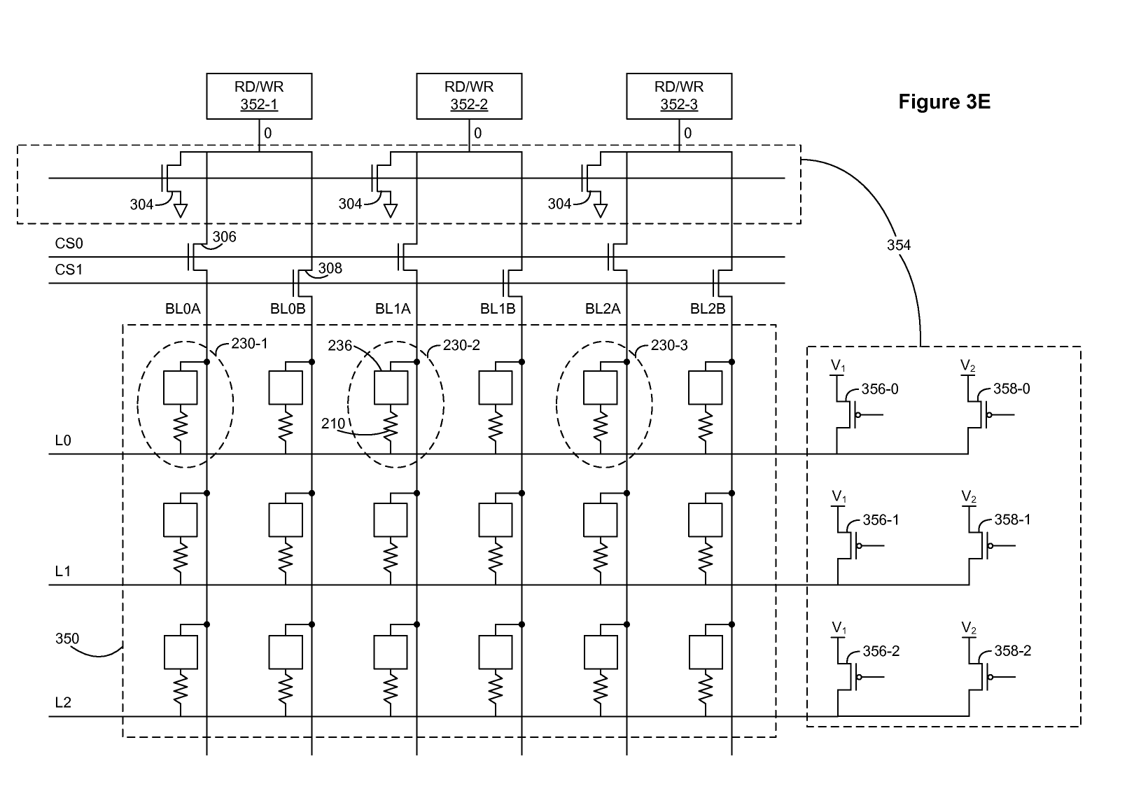

Resistive change memory cells with endurance such as that illustrated in FIG. 1 include three-terminal resistive change memory cells and two-terminal resistive change memory cells. FIGS. 2A and 2B are schematic diagrams of respective three-terminal resistive change memory cells 200 (FIG. 2A) and 220 (FIG. 2B) in accordance with some embodiments. In resistive change memory cells 200 and 220, a pass gate 208 (e.g., a transistor 208) and a resistive memory element 210 are arranged in series between a node (or terminal) 202 and a node (or terminal) 206. Node 202 connects to a bit line (e.g., bit line BL0A, BL0B, BL1A, BL1B, BL2A, or BL2B, FIGS. 3A-3D) and node 206 connects to a source line (e.g., source line SL, FIGS. 3A-3D). The gate of pass gate 208 connects to a node (or terminal) 204 that connects to a word line (e.g., word line WL0, WL1 or WL2, FIGS. 3A-3D). The order of pass gate 208 and resistive memory element 210 is reversed in resistive change memory cell 220 as compared to resistive change memory cell 200: in resistive change memory cell 200 the pass gate 208 connects directly to node 202 and resistive memory element 210 connects directly to node 206, while in resistive change memory cell 220 the resistive memory element 210 connects directly to node 202 and pass gate 208 connects directly to node 206.

To program resistive change memory cells 200 and 220, a logic-high (“H”) signal is applied to the gate of pass gate 208 via node 204 to turn on pass gate 208, and a programming voltage is applied between nodes 202 and 206 for a specified duration. In some embodiments, a positive set voltage V_{SET} is applied between nodes 202 and 206 (e.g., V_{SET} is a positive voltage relative to node 206) for a first duration to perform a set operation and a negative reset voltage −V_{RESET} is applied between nodes 202 and 206 (e.g., −V_{RESET} is a negative voltage relative to node 206) for a second duration to perform a reset operation. Note that the first duration and the second duration are typically equal. Also note that this specification refers to a logic-high (“H”) signal being applied to a gate to turn on pass gate 208. However, a voltage other than the logic-high (“H”) signal and that is sufficient to turn on the pass gate may be applied to the pass gate. Similarly, this specification refers to a logic-low (“L”) signal being applied to pass gate 208 to turn off the pass gate. However, a voltage other than the logic-low (“L”) signal and that is sufficient to turn off the pass gate may be applied to the pass gate.

In some embodiments, to perform a restore operation for the resistive change memory cells 200 and 220, the logic-high signal is applied to the gate of pass gate 208 via node 204 to turn on the pass gate 208, and a negative restore voltage −V_{RESTORE} is applied between the nodes 202 and 206 (e.g., −V_{RESTORE} is a negative voltage relative to node 206) for a third duration. In some implementations, voltage V_{RESTORE} is greater in magnitude than voltage V_{RESET}. In some implementations, voltage −V_{RESTORE} is applied between nodes 202 and 206 for a longer duration in the restore operation than the voltage −V_{RESET} is applied between nodes 202 and 206 in the reset operation. In other words, the third duration is greater than the second duration. Alternatively, the restore operation is performed by applying −V_{RESET} (as opposed to −V_{RESTORE}) between nodes 202 and 206 for a longer duration than for the reset operation.

FIGS. 2C and 2D are schematic diagrams of respective two-terminal resistive change memory cells 230 (FIG. 2C) and 240 (FIG. 2D). In resistive change memory cells 230 and 240, the resistive memory element 210 is arranged in series with a nonlinear conductive element 236 between a node 232 and a node 234. Node 232 connects to a bit line (e.g., bit line BL0A, BL0B, BL1A, BL1B, BL2A, or BL2B, FIG. 3E) and node 234 connects to a conductive line distinct from the bit line (e.g., line L0, L1 or L2, FIG. 3E). Nonlinear conductive element 236 has a non-linear current-voltage characteristic that reduces parasitic leakage currents in arrays of resistive change memory cells 230 or 240 (e.g., in array 350, FIG. 3E). In some embodiments, nonlinear conductive element 236 conducts (either unidirectionally or bidirectionally) only when a voltage across the nonlinear conductive element 236 exceeds a threshold voltage V_{TH} (e.g., a diode drop). In some embodiments, the nonlinear conductive element 236 is implemented as a diode. In some other embodiments, the nonlinear conductive element 236 is implemented as two diodes arranged in parallel but with opposite orientations, to provide bidirectional conductivity. The order of the resistive memory element 210 and nonlinear conductive element 236 is reversed in resistive change memory cell 240 as compared to resistive change memory cell 230: in resistive change memory cell 230 the nonlinear conductive element 236 connects directly to node 232 and resistive memory element 210 connects directly to node 234, while in resistive change memory cell 240 the resistive memory element 210 connects directly to node 232 and nonlinear conductive element 236 connects directly to node 234.

The two-terminal resistive change memory cells 230 and 240 are programmed and restored in similar manners to the three-terminal resistive change memory cells 200 and 220, except that there is no pass gate to turn on and the programming and restore voltages are adjusted to account for threshold voltage V_{TH}. For example, instead of applying V_{SET}, −V_{RESET}, or −V_{RESTORE}, respectively, (V_{SET}+V_{TH}), −(V_{RESET}+V_{TH}), or −(V_{RESTORE}+V_{TH}) are applied between nodes 232 and 234.

Resistive change memory cells such as resistive change memory cells 200, 220, 230, or 240 are situated in an array in a resistive change memory device. FIG. 3A illustrates an array 300 of resistive change memory cells 200 (FIG. 2A), including resistive change memory cells 200-1, 200-2, and 200-3, in accordance with some embodiments. While the array 300 is made up of resistive change memory cells 200, it alternatively could be made up of resistive change memory cells 220 (FIG. 2B). Word lines WL0, WL1, and WL2 extend across respective rows of resistive change memory cells 200 in the array 300; each of the word lines WL0, WL1 and WL2 is coupled to the gates of the pass gates 208 of the resistive change memory cells 200 in a respective row. Bit lines BL0A, BL0B, BL1A, BL1B, BL2A, and BL2B extend across respective columns of resistive change memory cells 200 in the array 300; each of the bit lines BL0A, BL0B, BL1A, BL1B, BL2A, and BL2B couples to the sources of the pass gates 208 of the resistive change memory cells 200 in a respective column. (The number of rows and columns shown for array 300 is limited for visual clarity; the array may include additional rows and columns.) The source of each respective pass gate 208 corresponds to a node 202 (FIG. 2A). In some implementations, each bit line is coupled to a respective read/write (RD/WR) circuit 302 and to a pull-down transistor 304 (e.g., an n-type MOSFET).

In the implementation shown in FIG. 3A, a pair of bit lines (e.g., BL0A and BL0B) shares a single read/write circuit 302 (e.g., 302-1), as controlled by the transistors 306 and 308. Bit line BL0A is coupled to read/write circuit 302-1 and to a pull-down transistor 304 by applying a logic-high (“H”) column-select signal CS0 to the gate of a respective transistor 306, thereby turning on the respective transistor 306. Additionally, a logic-low (“L”) column select signal CS1 is applied to the gate of a respective transistor 308 to decouple bit line BL0B from read/write circuit 302-1. Likewise, bit line BL0B is coupled to read/write circuit 302-1 and to a pull-down transistor 304 by applying a logic-high (“H”) column-select signal CS1 to the gate of a respective transistor 308. Additionally, a logic-low (“L”) column select signal CS0 is applied to the gate of a respective transistor 306 to decouple bit line BL0A from read/write circuit 302-1.

Each of the word lines WL0, WL1 and WL2, bit lines BL0A, BL0B, BL1A, BL1B, BL2A, and BL2B, and source line SL is a distinct conductive line. A source line SL connects to each resistive change memory cell 200 in the array 300. For example, the source line SL connects to the resistive memory element 210 of each resistive change memory cell 200 (e.g., via node 206, FIG. 2A). The source line SL also connects to the drains of pull-up transistors (e.g., p-type MOSFETs) 312 and 314. The source of the pull-up transistor 312 connects to a power supply that supplies a reset voltage V_{RESET} and the source of the pull-up transistor 314 connects to a power supply that supplies a restore voltage V_{RESTORE}. The source line SL thus can be coupled to either V_{RESET} or V_{RESTORE} via respective pull-up transistors 312 and 314. For example, the source line SL is coupled to V_{RESET} when a logic-low (“L”) complementary write-enable signal /EN_WR is applied to the gate of the pull-up transistor 312 and is coupled to V_{RESTORE} when a logic-low (“L”) complementary restore-enable signal /EN_RE is applied to the gate of the pull-up transistor 314. A restore-enable signal EN_RE (e.g., the complement of /EN_RE) is also applied to the gates of the pull-down transistors 304, the drains of which are connected to ground (sometimes herein called circuit ground). The source line SL thus is coupled to V_{RESTORE} during a restore operation, while any bit lines coupled to the transistors 304 through transistors 306 or 308 are simultaneously grounded. In some implementations, the array 300 includes a plurality of source lines. In these implementations, a respective source line connects a respective subset of resistive change memory cells 200 in the array 300. In one example, a respective source line is connected to the resistive change memory cells 200 in each word line; in other examples, a respective source line is connected to the resistive change memory cells 200 in two or more word lines, a respective source line is connected to the resistive change memory cells 200 in each bit line, or a respective source line is connected to the resistive change memory cells 200 in two or more bit lines.

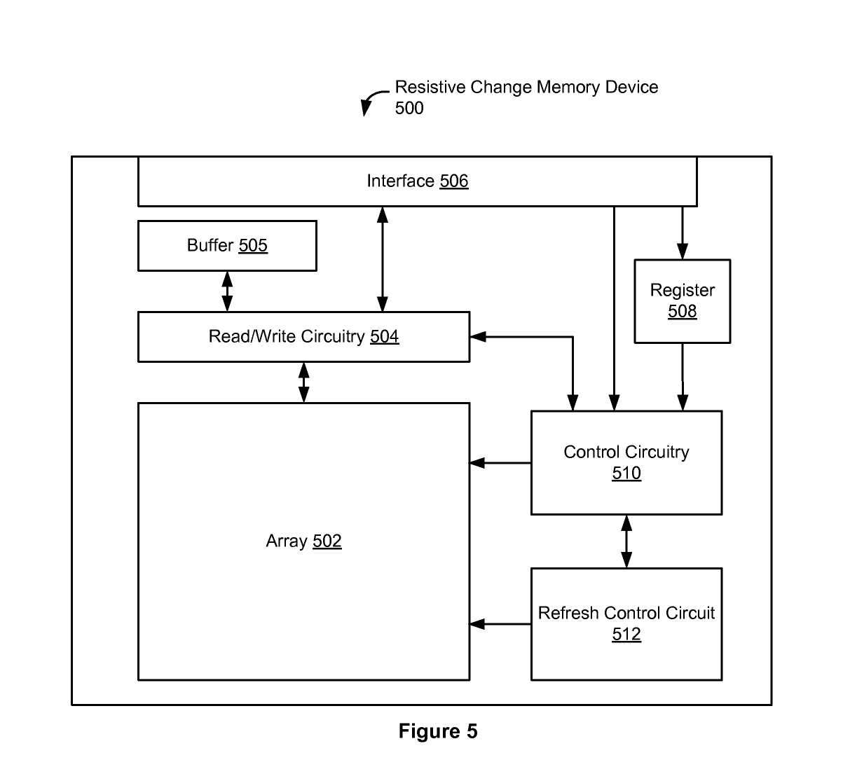

The pull-down transistors 304, pull-up transistors 312 and 314, and power supplies supplying the voltages V_{RESET} and V_{RESTORE} together constitute control circuitry 310 (e.g., control circuitry 510, FIG. 5). The pull-down transistors 304 and pull-up transistors 312 and 314 serve as bias circuits to ground the bit lines and couple the source line SL to either voltage V_{RESET} or voltage V_{RESTORE}, respectively.

In the example of FIG. 3A, biasing conditions are applied to the resistive change memory cells 200-1, 200-2, and 200-3 to simultaneously perform (or perform within a predetermined time each other) a set operation for the resistive change memory cell 200-1 and a reset operation for the resistive change memory cell 200-2 while not programming the resistive change memory cell 200-3. A logic-high signal is applied to the word line WL0 to turn on the pass gates 208 in the row corresponding to the word line WL0 and thereby couple the resistive memory elements 210 in the row to the corresponding bit lines. Logic-low signals are applied to the other word lines WL1, WL2, etc. to decouple the resistive memory elements in these rows from the corresponding bit lines. A logic-high column-select signal CS0 is applied to the transistors 306 to couple the bit lines BL0A, BL1A, and BL2A to respective read/write circuits 302-1, 302-2, and 302-3, while a logic-low column-select signal CS1 is applied to the transistors 308 to decouple the bit lines BL0B, BL1B, and BL2B from the respective read/write circuits 302-1, 302-2, and 302-3. The read-write circuit 302-1 provides a voltage of (V_{SET}+V_{RESET}) to the bit line BL0A. Simultaneously (or within a predetermined time of each other), the read-write circuit 302-2 provides a voltage of 0V to the bit line BL1A and the read-write circuit 302-3 provides a voltage of V_{RESET} to the bit line BL2A. A logic-low complementary write-enable signal /EN_WR is applied to the gate of the pull-up transistor 312, thus turning on the pull-up transistor 312 and providing a voltage of V_{RESET} to the source line SL. The voltage applied to each of the resistive change memory cells 200-1, 200-2, and 200-3 is the difference between the respective bit line voltage and the source line SL voltage. The voltage applied to resistive change memory cell 200-1 is (V_{SET}+V_{RESET})−V_{RESET}=V_{SET}, so that a set operation is performed on resistive change memory cell 200-1. The voltage applied to resistive change memory cell 200-2 is 0−V_{RESET}=−V_{RESET}, so that a reset operation is performed on resistive change memory cell 200-2. The voltage applied to resistive change memory cell 200-3 is V_{RESET}−V_{RESET}=0V, so that neither a set nor a reset operation is performed on resistive change memory cell 200-2; as a result, resistive change memory cell 200-2 remains in its previous state. As discussed above, the voltage applied to each of the resistive change memory cells 200-1, 200-2, and 200-3 is removed after a duration appropriate for the programming operation.

FIG. 3A thus illustrates how to perform set and reset operations for resistive change memory cells 200 in the array 300. FIG. 3B illustrates biasing conditions for simultaneously restoring (or restoring within a predetermined time of each other) multiple resistive change memory cells 200 in a row in the array 300 in accordance with some embodiments. Specifically, FIG. 3B illustrates a restore operation for the resistive change memory cells 200 in the row corresponding to word line WL0, which are accessed in response to column-select signal CS0. In some embodiments, these resistive change memory cells 200, which include the resistive change memory cells 200-1, 200-2, and 200-3, correspond to a page or other logical unit of data.

In the example of FIG. 3B, a logic-high signal is applied to the word line WL0 and logic-low signals are applied to the other word lines WL1, WL2, etc., thus enabling access to resistive change memory cells in the row corresponding to word line WL0 but not to resistive change memory cells in the other rows. A logic-high column-select signal CS0 is applied to the transistors 306 and a logic-low column-select signal CS1 is applied to the transistors 308, thereby coupling the resistive change memory cells to be restored to the pull-down transistors 304 via corresponding bit lines BL0A, BL1A, BL2A, etc. A logic-high restore-enable signal EN_RE is applied to the gates of the transistors 304, thus grounding the bit lines BL0A, BL1A, BL2A, etc. A logic-low complementary restore-enable signal /EN_RE is applied to the gate of the transistor 314, thereby providing V_{RESTORE} to the source line SL. The voltage across the resistive change memory cells to be restored is the difference between the bit line and source line SL voltages, which equals −V_{RESTORE}, the voltage corresponding to the restore operation. The restore voltage applied to the resistive change memory cells 200-1, 200-2, and 200-3 is removed after a duration appropriate for the restore operation.

FIG. 3B shows a restore operation performed on half of the resistive change memory cells 200 in a single row. In some embodiments, every resistive change memory cell 200 in a row is restored by concurrently applying logic-high column-select signals CS0 and CS1 to the gates of the transistors 306 and 308, and otherwise biasing the array 300 as shown in FIG. 3B.

FIG. 3C illustrates biasing conditions for simultaneously restoring (or restoring within a predetermined time of each other) every resistive change memory cell 200 in the array 300 in accordance with some embodiments. Logic-high column-select signals CS0 and CS1 are concurrently applied to the gates of the transistors 306 and 308, turning on both transistors 306 and 308. Logic-high signals are simultaneously applied (or applied within a predetermined time of each other) to every word line WL0, WL1, WL2, etc., to couple every resistive change memory cell 200 to its corresponding bit line. The array 300 is otherwise biased as shown in FIG. 3B. As a result, −V_{RESTORE} is applied to every resistive change memory cell 200 in the array 300 simultaneously (or within a predetermined time of each other), thus restoring every resistive change memory cell 200 in parallel. In some implementations, the logic-high signals are simultaneously applied (or applied within a predetermined time of each other) to a subset of the word lines WL0, WL1, WL2, etc., to couple resistive change memory cells 200 in the subset of word lines to their corresponding bit lines. The restore voltage applied to the resistive change memory cells in the array 300 is removed after a duration appropriate for the restore operation.

The examples of FIGS. 3A-3C include a first power supply to supply a first voltage V_{RESET} when programming operations (e.g., set and reset operations) are performed on the resistive change memory cells 200 and a second power supply to supply a second voltage V_{RESTORE} for when performing a restore operation on the resistive change memory cells 200. In some embodiments, however, a single configurable power supply supplies both voltages. FIG. 3D illustrates an array 300 in which the source line SL is coupled to a configurable power supply 324 via a pull-up transistor 322 (e.g., a p-type MOSFET) controlled by a complementary enable signal /EN. The complementary enable signal /EN is asserted both for programming and restore operations, to couple the source line SL to the configurable power supply 324, which supplies a voltage V_{CONFIG} during these operations. The configurable power supply 324 is configurable to provide voltage V_{RESET} during programming operations (e.g., set and reset operations) and voltage V_{RESTORE} during restore operations. The pull-down transistors 304, pull-up transistor 322, and configurable power supply 324 together constitute control circuitry 320 (e.g., control circuitry 510, FIG. 5).

FIGS. 3A-3D show an array 300 of three-terminal resistive change memory cells 200. Restore operations also may be performed on two-terminal resistive change memory cells, such as resistive change memory cells 230 (FIG. 2C) or 240 (FIG. 2D). FIG. 3E shows an array 350 of two-terminal resistive change memory cells 230 in accordance with some embodiments. While the array 350 is made up of resistive change memory cells 230, it alternatively could be made up of resistive change memory cells 240 (FIG. 2D). Conductive lines L0, L1, L2, etc. extend across respective rows of resistive change memory cells 230. The conductive lines L0, L1, L2, etc. are distinct from the bit lines, although the bit lines may also be referred to as conductive lines. Each conductive line L0, L1, L2, etc. connects to the resistive memory elements 210 of the resistive change memory cells 230 in its row (e.g., via nodes 234, FIG. 2C). Each conductive line L0, L1, L2, etc. may be coupled to a first power supply supplying a first voltage V₁ via a first pull-up transistor 356 and to a second power supply supplying a second voltage V₂ via a second pull-up transistor 358. Note that conductive lines L0, L1, L2, etc., may be referred to as word lines.

To perform a reset operation for the resistive change memory cell 230-1, transistors 306 and 356-0 are turned on. The read/write circuit 352-1 (or alternatively, the respective pull-down transistor 304) grounds the bit line BL0A and the first power supply supplies the first voltage V₁ corresponding to the reset operation (e.g., V_{RESET}+V_{TH}) to the conductive line L0. The first voltage V₁ applied to the resistive change memory cell 230-1 is removed after a predetermined duration appropriate for the reset operation.

To perform a restore operation for the resistive change memory cell 230-1, the transistors 306 and 358-0 are turned on. The respective pull-down transistor 304 (or alternatively, the read/write circuit 352-1) grounds the bit line BL0A and the second power supply supplies the second voltage V₂ corresponding to the restore operation (e.g., V_{RESTORE}+V_{TH}) to the conductive line L0. The second voltage V₂ applied to the resistive change memory cell 230-1 is removed after a duration appropriate for the restore operation.

Restore operations may be performed in parallel for multiple resistive change memory cells 230 in one or more rows (e.g., every other resistive change memory cell in a row, every resistive change memory cell in a row, or every resistive change memory cell in the array 350) through appropriate biasing of the conductive lines and bit lines, by analogy to the three-terminal examples of FIGS. 3B-3C. Similarly, reset operations may be performed in parallel for multiple resistive change memory cells 230 in one or more rows.

To perform a set operation for resistive change memory cell 230-1, the transistor 306 is turned on, the write/read circuit 352-1 provides a voltage corresponding to the set operation (e.g., V_{SET}+V_{TH}) to the bit line BL0A, and the conductive line L0 is grounded (e.g., using a pull-down transistor, not shown). The voltage corresponding to the set operation applied to the resistive change memory cell 230-1 is removed after a duration appropriate for the set operation.

In some embodiments, the first power supply and the second power supply are replaced with a single configurable power supply that is configurable to supply the first voltage V₁ and the second voltage V₂, during reset and restore operations, respectively, by analogy to the configurable power supply 324 supplying the voltage V_{CONFIG} of FIG. 3D. For example, the single configurable power supply is configurable to supply 0V, the first voltage V₁, and the second voltage V₂, during set, reset, and restore operations, respectively.

In some embodiments, resistive change memory cells to be restored (e.g., in accordance with the examples of FIGS. 3A-3E) are reset before being restored, to avoid high currents on the corresponding bit lines and source lines or word lines during the restore operation.

FIGS. 3A-3E illustrate reset and restore operations performed by applying specified voltages (e.g., V_{RESET} and V_{RESTORE}) to resistive change memory cells for a predetermined duration. For example, the voltage applied during a restore operation (e.g., V_{RESTORE}) is greater than the voltage applied during a reset operation (e.g., V_{RESET}) and/or is applied for a longer duration than the voltage that is applied during a reset operation. Alternatively, reset and restore operations are performed by applying specified currents to resistive change memory cells for a predetermined duration. For example, the restore current is greater than the reset current and/or is applied for a longer duration than the reset current. As discussed above, in some implementations, the voltage used during the reset operation (e.g., V_{RESET}) is the same voltage as the voltage used during the restore operation (e.g., V_{RESTORE}). In these implementations, the voltage used during the restore operation (e.g., V_{RESTORE}=V_{RESET}) is applied for a longer duration than the voltage used during the reset operation is applied.

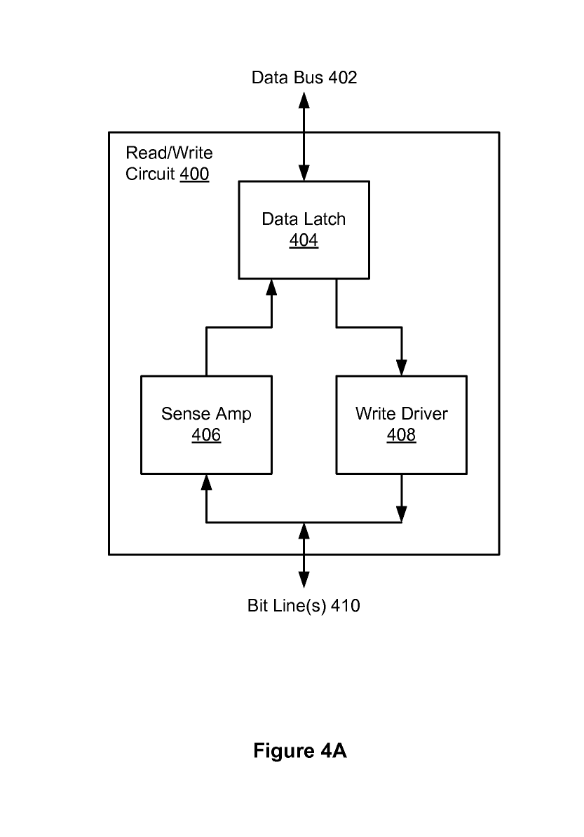

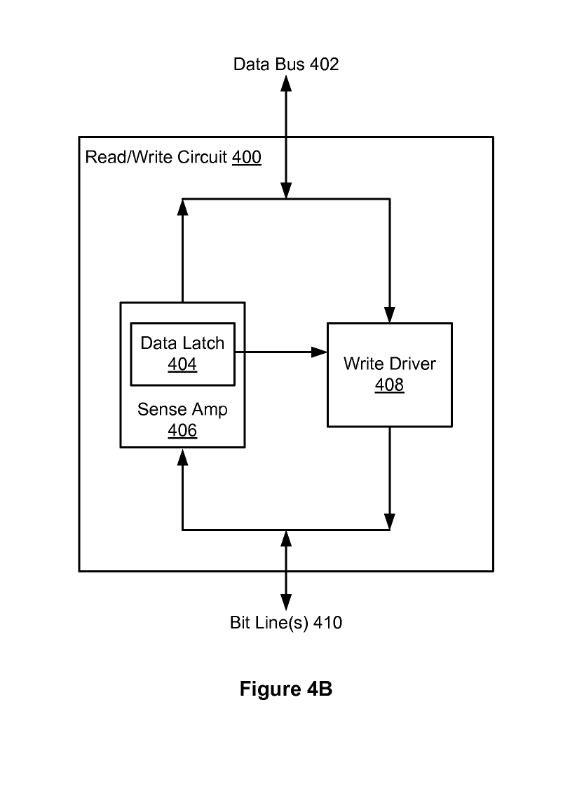

FIG. 4A is a block diagram illustrating a read/write circuit 400 in accordance with some embodiments. The read/write circuit 400 is an example of a read/write circuit 302 (FIGS. 3A-3D) or 352 (FIG. 3E). One or more bit lines 410 are coupled to a sense amplifier 406 and a write driver 408. In one example, read/write circuit 400 corresponds to the read/write circuit 302-1 (FIGS. 3A-3D) and the one or more bit lines 410 correspond to the bit lines BL0A and BL0B (FIGS. 3A-3D). In read/write circuit 400, sense amplifier 406 is arranged in parallel with write driver 408, both of which are coupled to a data latch 404. The sense amplifier 406 and write driver 408 thus are both coupled between the bit line(s) 410 and the data latch 404.

FIG. 4B is a block diagram illustrating an alternative implementation of read/write circuit 400 in accordance with some embodiments. As illustrated in FIG. 4B, sense amp 406 includes data latch 404. Furthermore, sense amp 406 and write driver 408 are coupled in parallel with each other between the data bus 402 and bit line(s) 410.

The following discussion refers to either of the read/write circuits 400 illustrated in FIGS. 4A and 4B. The sense amplifier 406 determines values of data read from resistive change memory cells connected to the bit line(s) 410 and provides the determined values to the data latch 404. Data latch 404 stores the values of the data and forwards the values onto a data bus 402. Data bus 402 is coupled, for example, to an interface (e.g., interface 506, FIG. 5) to transmit the data to a separate device (e.g., to a memory controller that requested the data.) Data bus 402 also provides data to data latch 404 (e.g., data provided by a memory controller for storage in the resistive change memory device). Data latch 404 stores the data and forwards the data to write driver 408, which drives the data onto bit line(s) 410 by supplying to the bit line(s) 410 the appropriate voltages for set or reset operations, depending on the value(s) of the data. Write driver 408 thus is used to program resistive change memory cells connected to the bit line(s) 410. Examples of this programming are described above with respect to FIGS. 3A and 3E. Data latch 404 also provides data to write driver 408 during a refresh operation or a restore operation, as described in more detail below.

In some embodiments, restore operations are performed on resistive change memory cells in a single row, as described with regard to FIGS. 3B and 3E. In some of these embodiments, the data from the resistive change memory cells is stored in data latches 404 before the restore operation and then written back to the resistive change memory cells after the restore operation, thus allowing the data to be retained. Before the restore operation, sense amplifiers 406 read the data from the resistive change memory cells and provide the data to the data latches 404. After the restore operation, the data latches 404 provide the data to the write drivers 408, which program the data back into the resistive change memory cells. Alternatively, the data is stored in a buffer in the resistive change memory device (e.g., the buffer 500, FIG. 5) or in an external device during the restore operation.

FIG. 5 is a block diagram of a resistive change memory device 500 in accordance with some embodiments. FIG. 5 is not intended to be a complete schematic diagram of memory device 500 but instead illustrates components of memory device 500 corresponding to disclosed embodiments. Memory device 500 includes an array 502 (e.g., array 300, FIGS. 3A-3D, or array 350, FIG. 3E) of resistive change memory cells (e.g., resistive change memory cells 200, 220, 230, or 240, FIGS. 2A-2D). Coupled to array 502 are read/write circuitry 504, which includes a plurality of read/write circuits 400 (e.g., the read/write circuits shown in either FIG. 4A or FIG. 4B, read/write circuits 302, FIGS. 3A-3D, or read/write circuits 352, FIG. 3E), and control circuitry 510 (e.g., control circuitry 310, FIGS. 3A-3C, 320, FIG. 3D, or 354, FIG. 3E). The read/write circuitry 504 is coupled to an interface 506 (e.g., via a data bus 402, FIGS. 4A and 4B) of memory device 500, as described with reference to FIGS. 4A and 4B.

In some embodiments, memory device 500 includes a buffer 505 to store data from resistive change memory cells being restored. Prior to a restore operation, data from the resistive change memory cells to be restored is read by read/write circuitry 504 and provided to buffer 505 for storage. After the restore operation, buffer 505 provides the data to the read/write circuitry 504, which writes the data back into the restored resistive change memory cells. In some embodiments, buffer 505 is used to store data from resistive change memory cells in multiple rows that are being restored in parallel. In some embodiments, when restoring resistive change memory cells in a single row, the data is stored in buffer 505 or alternatively in data latches 404 (e.g., FIGS. 4A and 4B).

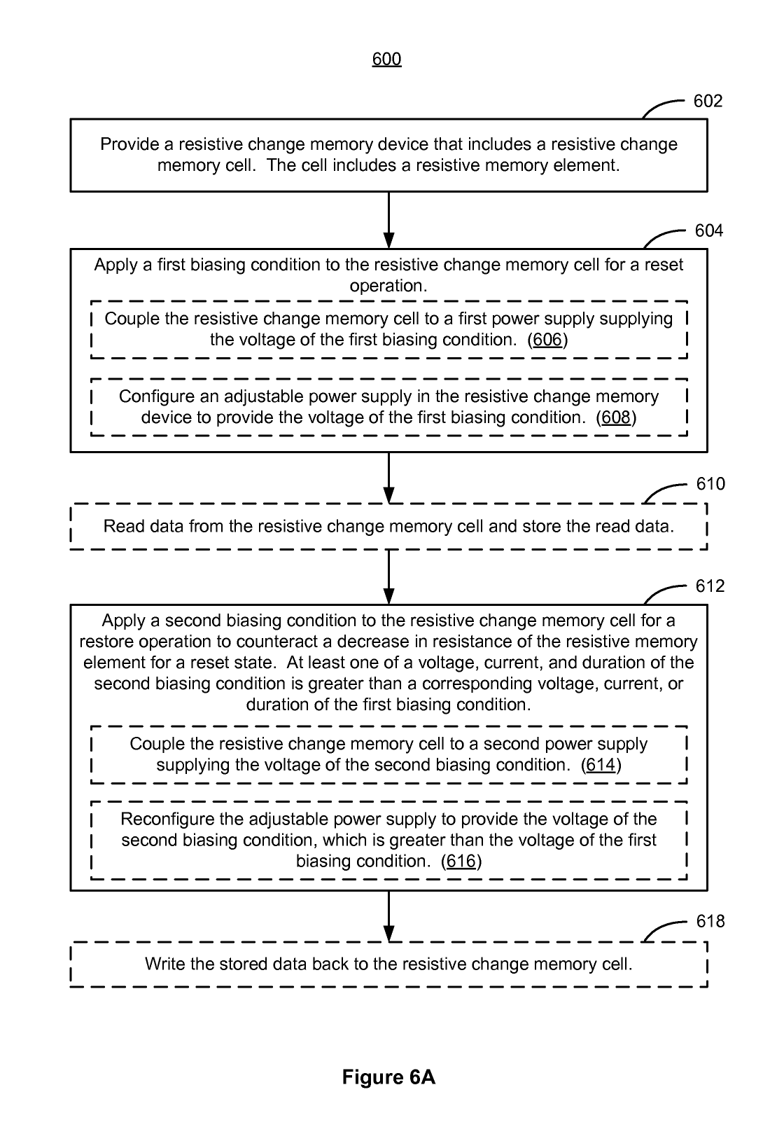

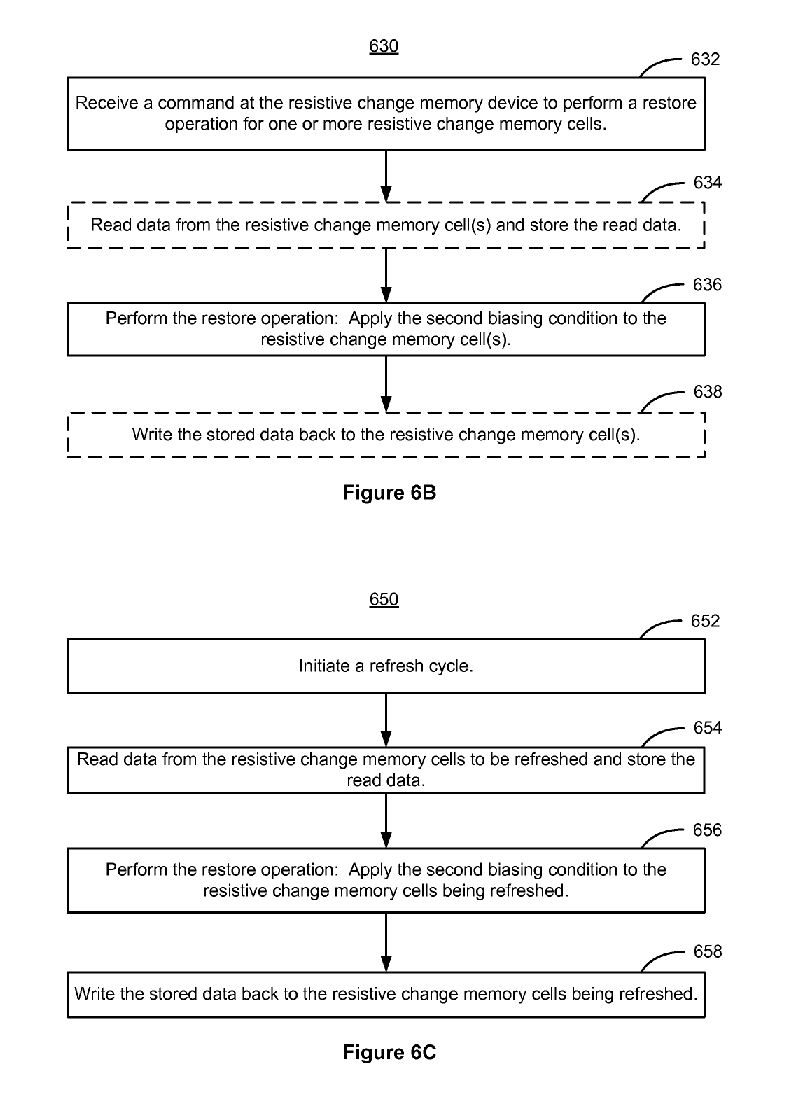

In some embodiments, the resistive change memory cells in array 502 have limited data retention times and thus are volatile. In other embodiments, the resistive change memory cells are nonvolatile. In embodiments with volatile resistive change memory cells, memory device 500 includes a refresh control circuit 512 to periodically refresh the data in the resistive change memory cells. These periodic refresh operations are referred to as refresh cycles. Refresh control circuit 512 is coupled to control circuitry 510 to instruct control circuitry 510 to perform restore operations during the refresh cycles, as described below for the method 650 (FIG. 6C), for example.

In some embodiments, interface 506 is configured to receive commands to perform restore operations. The commands are received, for example, from an external device (e.g., a memory controller). In response to such a command, interface 506 instructs control circuitry 510 to perform a restore operation, as described below for the method 630 (FIG. 6B), for example.

In some embodiments, memory device 500 includes a register 508 to store one or more settings for restore operations. For example, in some implementations, register 508 stores a setting specifying the restore voltage V_{RESTORE} to be used for the restore operations and/or a setting specifying the duration for which the restore voltage V_{RESTORE} is applied during the restore operations. Alternatively, register 508 stores a setting specifying a restore current to be used for the restore operations and/or a setting specifying the duration for which the restore current is applied during the restore operations. Register 508 is coupled to control circuitry 510 to apply the setting(s) to control circuitry 510. In some embodiments, the setting(s) stored in register 508 are set externally. For example, interface 506 receives a command from an external device specifying one or more settings; in response, the specified setting(s) are stored in register 508.

FIG. 6A is a flow diagram illustrating a method 600 of operating a resistive change memory device in accordance with some embodiments. In method 600, a resistive change memory device (e.g., memory device 500, FIG. 5) is provided (602) that includes a resistive change memory cell (e.g., a resistive change memory cell 200, 220, 230, or 240, FIG. 2D). The resistive change memory cell includes a resistive memory element (e.g., an element 210, FIGS. 2A-2D).

A first biasing condition is applied (604) to a resistive change memory cell for a reset operation. In some embodiments, the resistive change memory cell is coupled (606) to a first power supply (e.g., the power supply providing the voltage V_{RESET} in FIGS. 3A-3C) that supplies the voltage of the first biasing condition. In some embodiments, a configurable power supply (e.g., the configurable power supply 324 producing the voltage V_{CONFIG} in FIG. 3D) in the resistive change memory device is configured (608) to provide the voltage of the first biasing condition. As discussed above, in accordance with the first biasing condition, the voltage for the reset operation is applied to the resistive change memory cell for a first predetermined duration.

A second biasing condition is applied (612) to the resistive change memory cell for a restore operation to counteract a decrease in resistance of the resistive memory element for a reset state. At least one of a voltage, current, and duration of the second biasing condition is greater than a corresponding voltage, current, or duration of the first biasing condition. In some embodiments, the resistive change memory cell is coupled (614) to a second power supply (e.g., the power supply providing the voltage V_{RESTORE} in FIGS. 3A-3C) that supplies the voltage of the second biasing condition. In some embodiments, the adjustable power supply (e.g., the configurable power supply 324 producing the voltage V_{CONFIG} in FIG. 3D) is reconfigured (616) to provide the voltage of the second biasing condition, which is greater than the voltage of the first biasing condition. As discussed above, in accordance with the second biasing condition, the voltage for the restore operation is applied to the resistive change memory cell for a second predetermined duration.

Note that the difference between the first predetermined duration and the second predetermined duration, and the magnitudes of the voltages associated with the application of the first biasing condition and the second biasing condition discussed above with reference to FIGS. 3A-3E apply to the discussion of FIGS. 6A-6C.

In some embodiments, before applying (612) the second biasing condition to the resistive change memory cell, data is read (610) from the resistive change memory cell (e.g., using a sense amplifier 406, FIGS. 4A and 4B) and stored (e.g., in data latch 404, FIGS. 4A and 4B, or buffer 505, FIG. 5). After applying (612) the second biasing condition to the resistive change memory cell, the stored data is written (618) back to the resistive change memory cell (e.g., using the write driver 408, FIGS. 4A and 4B).

In some embodiments, applying (612) the second biasing condition is performed simultaneously (or performed within a predetermined time of each other) for multiple resistive change memory cells. For example, the second biasing condition is applied in parallel to multiple resistive change memory cells in a row, to every resistive change memory cell in a row, to multiple resistive change memory cells (or every resistive change memory cell) in multiple rows, and/or to every resistive change memory cell in an array (e.g., array 300, FIGS. 3A-D, or array 350, FIG. 3E). In some embodiments, the read operation 610 is performed on every resistive change memory cell to be restored, and the write operation 618 is performed on every resistive change memory cell that has been restored.

Method 600 thus helps to counteract a decrease in the reset resistance of a resistive memory element in a resistive change memory cell resulting from repeated use of the resistive change memory cell. While method 600 includes a number of operations that appear to occur in a specific order, method 600 can include more or fewer operations, an order of two or more operations may be changed, and/or two or more operations may be combined into a single operation.

A restore operation may be performed in response to a command (e.g., a command from an external device), as illustrated in the method 630 of FIG. 6B in accordance with some embodiments. In method 630, a command is received (632) at a resistive change memory device (e.g., at interface 506 of memory device 500, FIG. 5) to perform a restore operation for one or more resistive change memory cells (e.g., one or more resistive change memory cells in array 300, FIGS. 3A-3D, or array 350, FIG. 3E). In response to the command, the restore operation is performed (636): the second biasing condition is applied to the one or more resistive change memory cells (e.g., in accordance with the applying operation 612, FIG. 6A).

In some embodiments, before performing (636) the restore operation, data is read (634) from the one or more resistive change memory cells (e.g., using sense amplifiers 406, FIGS. 4A and 4B) and stored (e.g., in data latches 404, FIGS. 4A and 4B, or buffer 505, FIG. 5). After performing (636) the restore operation, the stored data is written (638) back to the one or more resistive change memory cells (e.g., using write drivers 408, FIGS. 4A and 4B).

Method 630 thus provides a technique for controlling performance of a restore operation. While method 630 includes a number of operations that appear to occur in a specific order, method 630 can include more or fewer operations and/or two or more operations may be combined into a single operation.

A restore operation may be performed during a refresh cycle, as illustrated in the method 650 of FIG. 6C in accordance with some embodiments in which the resistive change memory cells are volatile. In method 650, a refresh cycle is initiated (652) in a resistive change memory device (e.g., the device 500, FIG. 5). For example, the refresh cycle is initiated under the control of refresh control circuit 512 (FIG. 5). In response, data is read (654) from the resistive change memory cells to be refreshed (e.g., using sense amplifiers 406, FIGS. 4A and 4B) and stored (e.g., in data latches 404, FIGS. 4A and 4B, or buffer 505, FIG. 5). The restore operation is performed (656): the second biasing condition is applied to the resistive change memory cells being refreshed (e.g., in accordance with the applying operation 612, FIG. 6A). After performing (656) the restore operation, the stored data is written (658) back to the resistive change memory cells being refreshed (e.g., using write drivers 408, FIGS. 4A and 4B).

Method 650 thus provides another technique for controlling performance of a restore operation. While method 650 includes a number of operations that appear to occur in a specific order, method 650 can include more or fewer operations and/or two or more operations may be combined into a single operation.

Methods 630 (FIG. 6B) and 650 (FIG. 6C) illustrate examples in which restore operations are performed in response to commands or refresh operations. Other examples of conditions that, in various implementations, trigger performance of restore operations include powering on the system that includes the resistive change memory device, calibrating the system that includes the resistive change memory device, performing a specified number of programming operations, and/or passage of a specified time.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain the principles of the inventions and their practical applications, to thereby enable others to best utilize the inventions and various embodiments with various modifications as are suited to the particular use contemplated.

What is claimed is:

1. A resistive change memory device, comprising:
a first conductive line,
a second conductive line;
a resistive change memory cell comprising a resistive memory element coupled between the first conductive line and the second conductive line; and
control circuitry to apply, via the first conductive line and the second conductive line, a first biasing condition to the resistive change memory cell for a reset operation and a second biasing condition to the resistive change memory cell for a restore operation, wherein at least one of a voltage, current, and duration of the second biasing condition is greater than a corresponding voltage, current, or duration of the first biasing condition, and the restore operation is to counteract a decrease in resistance of the resistive memory element for a reset state of the resistive change memory cell.

2. The resistive change memory device of claim 1,
wherein the resistive change memory cell additionally comprises a nonlinear conductive element in series with the resistive memory element, wherein the nonlinear conductive element and resistive memory element are coupled between the first conductive line and the second conductive line; and
wherein the first conductive line is a bit line and the second conductive line is a word line.

3. The resistive change memory device of claim 1, wherein the resistive change memory cell additionally comprises:
a pass gate in series with the resistive memory element, wherein the pass gate and resistive memory element are coupled between the first conductive line and the second conductive line; and
a third conductive line coupled to the pass gate;
wherein the first conductive line is a bit line, the second conductive line is a source line, and the third conductive line is a word line.

4. The resistive change memory device of claim 1, additionally comprising a latch coupled to the first conductive line, wherein the latch is configured to store data read from the resistive change memory cell prior to performance of the restore operation.

5. The resistive change memory device of claim 4, additionally comprising a sense amplifier coupled between the first conductive line and the latch, wherein the sense amplifier is configured to determine a value of the data read from the resistive change memory cell and to provide the value to the latch.

6. The resistive change memory device of claim 4, additionally comprising a write driver coupled to the latch and the first conductive line, wherein the write driver is configured to write the data stored in the latch to the resistive change memory cell after the performance of the restore operation.

7. The resistive change memory device of claim 1,
wherein the voltage of the second biasing condition is greater in magnitude than the corresponding voltage of the first biasing condition; and
wherein the control circuitry comprises:
a first power supply configured to supply the voltage of the first biasing condition;
a second power supply configured to supply the voltage of the second biasing condition;
a first transistor configured to couple the second conductive line to the first power supply during the reset operation; and
a second transistor configured to couple the second conductive line to the second power supply during the restore operation.

8. The resistive change memory device of claim 7, wherein the control circuitry additionally comprises a third transistor configured to ground the first conductive line during the reset and restore operations.

9. The resistive change memory device of claim 1,
wherein the voltage of the second biasing condition is greater in magnitude than the corresponding voltage of the first biasing condition; and
wherein the control circuitry comprises:
a power supply configured to supply the voltage of the first biasing condition during the reset operation and the voltage of the second biasing condition during the restore operation; and
a transistor to couple the second conductive line to the power supply during the reset and restore operations.

10. The resistive change memory device of claim 1, wherein the resistive change memory device comprises:
a plurality of first conductive lines, including the first conductive line;
a plurality of second conductive lines, including the second conductive line; and
a plurality of resistive change memory cells, including the resistive change memory cell, each of the respective resistive change memory cells comprising a respective resistive memory element coupled between a respective one of the plurality of second conductive lines and a respective one of the plurality of first conductive lines;
wherein the control circuitry is configured to simultaneously apply the second biasing condition to the plurality of resistive change memory cells for the restore operation.

11. The resistive change memory device of claim 10, wherein the control circuitry comprises:
a power supply configured to provide the voltage of the second set of biasing conditions for the restore operation;
a first bias circuit configured to couple the plurality of second conductive lines to the power supply; and
a plurality of second bias circuits configured to ground the plurality of first conductive lines for the restore operation.

12. The resistive change memory device of claim 10,
wherein the plurality of resistive change memory cells comprise a row of resistive change memory cells; and
wherein the resistive change memory device additionally comprises latches, each of the latches coupled to a respective one of the plurality of first conductive lines, and each of the latches configured to store data read from a respective one of the resistive change memory cells in the row prior to performance of the restore operation.

13. The resistive change memory device of claim 12, additionally comprising sense amplifiers, each sense amplifier coupled between a respective one of the plurality of first conductive lines and a respective one of the latches, wherein the sense amplifiers are configured to determine values of the data read from the resistive change memory cells and to provide the values to the latches.

14. The resistive change memory device of claim 12, additionally comprising write drivers, each write driver coupled to a respective one of the plurality of first conductive lines and a respective one of the latches, wherein the write drivers are configured to write the data stored in the latches to the resistive change memory cells after the performance of the restore operation.

15. The resistive change memory device of claim 12, additionally comprising a refresh control circuit coupled to the control circuitry, wherein the refresh control circuit is configured to instruct the control circuitry to perform the restore operation during a refresh cycle.

16. The resistive change memory device of claim 12, additionally comprising:
a third conductive line for the row of resistive change memory cells;
wherein the third conductive line for the row of resistive change memory cells is a the word line for the row of resistive change memory cells;
wherein each of the resistive change memory cells of the row comprises a pass gate in series with the resistive memory element and is coupled to the third conductive line; and
wherein the pass gate and resistive memory element are coupled between a respective first conductive line of the plurality of first conductive lines and a respective second conductive line of the plurality of second conductive lines.

17. The resistive change memory device of claim 10, additionally comprising a buffer configured to store data from the resistive change memory cells prior to performance of the restore operation and to provide the data to the resistive change memory cells after the performance of the restore operation.

18. The resistive change memory device of claim 1, additionally comprising an interface to receive a command to perform the restore operation, wherein the control circuitry is configured to apply the second biasing condition to the resistive change memory cell in response to the command.

19. The resistive change memory device of claim 1, additionally comprising an externally settable register to store one or more settings for the restore operation, wherein the control circuitry is configured to apply the second biasing condition to the resistive change memory cell in accordance with the one or more settings.

20. A method, comprising:
providing a resistive change memory device comprising a resistive change memory cell, the resistive change memory cell comprising a resistive memory element;
applying a first biasing condition to the resistive change memory cell for a reset operation; and
applying a second biasing condition to the resistive change memory cell for a restore operation to counteract a decrease in resistance of the resistive memory element for a reset state, wherein at least one of a voltage, current, and duration of the second biasing condition is greater than a corresponding voltage, current, or duration of the first biasing condition.
